(19) United States
(12) Patent Application Publication
(10) Pub. No.: US 2025/0157893 A1
(43) Pub. Date: May 15, 2025

(54) DISCRETE SEMICONDUCTOR DEVICE PACKAGE WITH LEAD FRAME CLIP

(71) Applicant: SEMICONDUCTOR COMPONENTS INDUSTRIES, LLC, Scottsdale, AZ (US)

(72) Inventors: Jie CHANG, Suzhou (CN); Sen SUN, Suzhou (CN); XiaoYing YUAN, Suzhou (CN); Sixin JI, NanTong (CN); AnAn XING, Suzhou (CN); Keunhyuk LEE, Suzhou (CN)

(73) Assignee: SEMICONDUCTOR COMPONENTS INDUSTRIES, LLC, Scottsdale, AZ (US)

(21) Appl. No.: 18/507,381

(22) Filed: Nov. 13, 2023

(51) Int. Cl. H01L 23/495; H01L 23/00; H01L 23/31

(52) U.S. Cl. CPC H01L 23/49513; H01L 23/3107; H01L 23/49562; H01L 24/45; H01L 24/83; H01L 2224/45124; H01L 2224/45147; H01L 2224/48472; H01L 2224/8384; H01L 2924/10272; H01L 2924/13091

(57) ABSTRACT

A package includes a semiconductor die attached to a die attach pad by a first sinter bond. The package further includes a clip having a first end and a second end. The first end of the clip is attached to a device contact pad on the semiconductor die by a second sinter bond and the second end of the clip is attached to a post of a lead by a joint. The package further includes a mold body encapsulating the semiconductor die.

### TECHNICAL FIELD

This description relates to packaging of semiconductor die and integrated circuits.

### BACKGROUND

A semiconductor package includes a metal, plastic, glass, or ceramic casing containing one or more semiconductor devices or integrated circuits. Individual components are fabricated on semiconductor wafers (commonly silicon, or silicon carbide wafers) before being diced into die, tested, and packaged. The package provides a means for connecting the semiconductor devices or integrated circuits to the external environment, such as printed circuit board, via leads such as lands, balls, or pins; and protection against threats such as mechanical impact, chemical contamination, and light exposure. With increasing demand for high-performance integrated circuits, improvements are needed in packaging technologies to address performance and reliability issues.

### SUMMARY

In a general aspect, a package includes a semiconductor die attached to a die attach pad by a first sinter bond, and a clip having a first end and a second end. The first end of the clip is attached to a device contact pad on the semiconductor die by a second sinter bond and the second end of the clip is attached to a post of a lead by a joint. The package further includes a mold body encapsulating the semiconductor die.

In a first aspect, the first sinter bond and the second sinter bond are low temperature silver-based sinter bonds.

In a second aspect, the lead with the second end of the clip attached to the post of the lead extends outside the mold body to form an external terminal of the package.

In a third aspect, the device contact pad is a source contact pad and wherein the external terminal is an external source terminal of the package.

In a fourth aspect, the device contact pad is a first device contact pad, and the lead is a first lead and the semiconductor die further includes a second device contact pad that is connected by a wire bond to a post of a second lead.

In a fifth aspect, the wire bond is an aluminum wire bond.

In the sixth aspect, the second device contact pad is a gate contact pad and the second lead extends outside the mold body to form an external gate terminal of the package.

In a seventh aspect the semiconductor die includes a silicon carbide (SiC) power transistor.

In a general aspect, a package includes a semiconductor die attached to a die attach pad on a substrate. The semiconductor die includes a source contact pad, a gate contact pad, and a source sense pad. The package further includes a mold body encapsulating the semiconductor die, and a clip connecting the source contact pad to a lead post of a lead forming an external terminal of the package. A first end of the clip is attached to the source contact pad by a sinter bond, and a second end of the clip is attached to a lead post by a fusion bond. The lead post is an end of a lead extending outside the mold body to form an external source terminal of the package.

In a first aspect, the fusion bond is a silver sinter bond.

In a second aspect, the fusion bond is a welding joint.

In a third aspect, the gate contact pad and a source sense pad are connected by wires bonded to a respective gate lead post and a respective source sense lead post.

In a fourth aspect, the wires are aluminum wires.

In a fifth aspect, the semiconductor die includes a silicon carbide (SIC) power transistor.

In a general aspect, a method includes sintering a semiconductor die to a die attach pad (DAP) in a lead frame structure, and connecting a source contact pad formed on the semiconductor die to a lead post of a lead with a clip. The method further includes encapsulating the semiconductor die in a mold body with the lead extending from the mold body as an external terminal of a package.

In a first aspect, sintering the semiconductor die to the DAP includes disposing a silver particle paste between the semiconductor die and the DAP; and applying pressure on the semiconductor die.

In a second aspect, connecting the source contact pad on the semiconductor die to a lead post of a lead with a clip includes sintering a first end of the clip to the source contact pad.

In a third aspect, sintering the first end of the clip to the source contact pad includes disposing a silver sinter preform on a top of first end of the clip abutting the source contact pad, and applying pressure to a backside of semiconductor die on which the source contact pad is formed.

In a fourth aspect, connecting a source contact pad formed on the semiconductor die to the lead post of the lead with the clip further includes welding a second end of the clip to the lead post of the lead.

In a fifth aspect, the semiconductor die includes a silicon carbide (SiC) power transistor.

The details of one or more implementations are set forth in the accompanying drawings and the description below. Other features will be apparent from the description and drawings, and from the claims.

### BRIEF DESCRIPTION OF THE DRAWINGS

FIG. 1 illustrates, in a cross-sectional view, a semiconductor device package.

FIG. 2 illustrates, in a plan view, shows, in a plan view, an assembly of components of a semiconductor die package at an intermediate stage of construction.

FIG. 3 schematically illustrates joining of an end of a metal clip to a lead post.

FIG. 4 illustrates an example reeled substrate frame.

FIG. 5 schematically illustrates sintering of an end of a metal clip to a source contact pad in a jig.

FIG. 6 is a flow chart illustrating a method for preparing a lead frame unit with a semiconductor die that is sinter bonded to a substrate.

FIGS. 7A through 7F illustrate a lead frame unit at various stages of a method for sinter bonding a semiconductor die to a die attach pad (DAP) in a lead frame structure.

FIG. 8 is a flow chart illustrating a method for preparing metal clips with a sinter preform for sinter bonding.

FIGS. 9A through 9H illustrate various stages of a process for disposing Ag sinter preforms on metal clips for sinter bonding.

FIG. 10 is a flow chart illustrating a method combining the results of the methods of FIG. 6 and FIG. 8 to fabricate a discrete semiconductor die package.

FIGS. 11A through 11D illustrate views of a package assembly at some of the steps of the method of FIG. 10.

FIGS. 12A through 12F illustrate views of a package assembly at some additional steps of the method of FIG. 10.

FIG. 13 is a flow chart illustrating an example method for packaging a semiconductor die.

### DETAILED DESCRIPTION

A semiconductor device package includes a semiconductor die mounted on a lead frame structure that includes leads providing external electrical connections (external to the package) for individual devices or integrated circuits in the semiconductor die. The semiconductor die can be mounted on a paddle or flag in the leadframe structure. Further, device contact pads on the semiconductor die are electrically connected using wire bonds (e.g., aluminum wire bonds) to respective ones of the leads. The leads, which extend to an outside of the package body, form external terminal pins that can be used to mount the package on a printed circuit board or terminal strip. In example implementations, the terminal pins can be installed in sockets or soldered to a printed circuit board (PCB) or terminal strip.

There can be many package types used in various applications. Some are defined by international, national, or industry standards, while others are particular to an individual manufacturer. The number and configuration of external terminal pins of a package type may be defined by international, national, or industry standards.

An example semiconductor die package can include a discrete semiconductor device, for example, a power transistor, a silicon carbide (SiC) MOSFET, or another device.

In a power module package, a semiconductor die is attached to a DAP (Die Attach Pad) on a lead frame that can form the external terminals of the package. Wires are soldered to connect contact pads (e.g., source, gate, and source sense contact pads) on the semiconductor die to individual lead posts on the lead frame to form the external terminals of the package. Some regulations restrict chemicals and heavy metals in electronic components, solder, and materials. This disclosure describes power module packaging that is compliant with at least some regulation directives. The power module packaging methods disclosed herein avoid the use of lead (PB) and other restricted chemicals.

In accordance with the principles of the present disclosure, in example packaging implementations, a sinter (e.g., silver (Ag) sinter, a silver-based sinter) may be used to mutually couple, bond, or attach two different components of a semiconductor die package. In some implementations, the two different components of the semiconductor die package may be joined (e.g., welded) or fused together without addition of any intervening materials (e.g., solder).

A disclosed power module package uses sintering (e.g., silver (Ag) sintering) to attach a semiconductor die to a DAP in a lead frame structure. Further, Ag sintering can be used to connect one end of a metal clip to the die and the second end of the metal clip to a lead post in the lead frame. In some implementations, the second end of the metal clip may be welded to the lead post.

In accordance with the principles of the present disclosure, in example packaging implementations, a sinter (e.g., a silver or a silver-based sinter) may be used to mutually couple, bond, or attach two different components of a semiconductor die package.

In a sintering process, a sinter species (e.g., Ag atoms) may diffuse into, and hold, the two different components together. Sintering improves reliability of the attachment (bonding) of the two components together by avoiding use of an intermediate joining layer (e.g., a solder or adhesive) that can crack, for example, on temperature cycling. In example implementations, for example, an Ag-based sinter can be used to attach a semiconductor die to a die attach pad (DAP) in a lead frame structure.

In example implementations, a copper clip may be used to connect a source contact pad on the semiconductor die to a source lead contact post in the lead frame structure to form an external source lead of the package.

In example implementations, a first end of the copper clip may be sintered to the source contact pad on the semiconductor die. In some example implementations, a second end of the copper clip is welded to the source lead contact post in the lead frame structure. In some other example implementations. The second end of the copper clip is sintered to the source lead contact post in the lead frame structure.

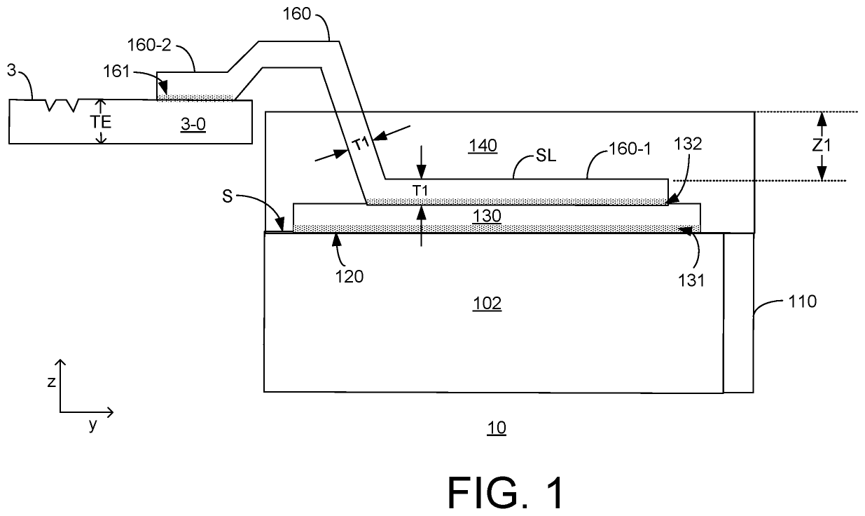

FIG. 1 shows a cross-sectional view of a package 10 that includes components that are coupled together by sintering (e.g., Ag sintering, etc.) or welding, in accordance with the principles of the present disclosure.

In package 10 (e.g., a discrete semiconductor device package) a semiconductor die 130 (e.g., a 1200V SiC MOSFET, maximum current ˜600 A, power ˜500 KW) is encapsulated in a mold body 140 made of an epoxy or a molding compound. Semiconductor die 130 may be disposed on a die attach pad (DAP) 120 on a surface S of a flag or pad 102 of a lead frame structure in the package. Semiconductor die 130 may be attached to DAP 120 by a sinter bond (e.g., Ag sinter 131). A lead 3 may include a lead portion lead portion 3-0 forming an external terminal of the package. Lead 3 may be connected to a device contact pad (e.g., a source contact pad, not shown) on the semiconductor die 130 by a metal clip 160.

Metal clip 160 may include a first end 160-1 that is attached to the source contact pad on semiconductor die and a second end 160-2 that is attached to lead 3 forming the external terminal of the package.

In at least example implementation, first end 160-1 of metal clip 160 may be attached to the source contact pad on semiconductor die by a sinter bond (e.g., Ag sinter 132). In at least example implementation, second end 160-2 of metal clip 160 may be attached by a fusion bond 161 to a lead post 3-0 of lead 3 forming the external terminal of the package. In some example implementations, fusion bond 161 may be a joint (e.g., a welding joint) formed, for example, by joining (e.g., welding) second end 160-2 of metal clip 160 to lead post 3-0 of lead 3. In some example implementations, fusion bond 161 may be formed by an Ag sinter between second end 160-2 of metal clip 160 and lead post 3-0 of lead 3.

In some example implementations, lead portion 3-0 of lead 3 forming the external terminal of the package may extend in a y direction and lie generally in an x-y plane. First end 160-1 that is attached to the source contact pad on semiconductor die may generally lie in another x-y plane (parallel to the device contact pad on semiconductor die 130) that is offset from the x-y plane of lead portion 3-0 by a distance Z1. Clip 160 may be bent to transition continuously over the distance Z1 from the x-y plane of second end 160-2 to the x-y plane of first end 160-1.

Lead 3 may have a thickness TE. Thickness TE may correspond to the thickness requirements for coupling the external terminal formed by lead 3 to a printed circuit board according to an industry standard for device packages (e.g., for a 1200V SiC MOSFET, maximum current ˜600 A, power ˜500 KW, device package). For example, for an industry standard D2PAK, thickness TE may be about 0.5 mm.

In example implementations, flag, or pad 102 may be coupled to a header portion (e.g., header 110) disposed above (e.g., in the y direction) the flag. Header 110 may be electrically connected to DAP 120 through the substrate and may be a drain or ground terminal for the semiconductor die in the package.

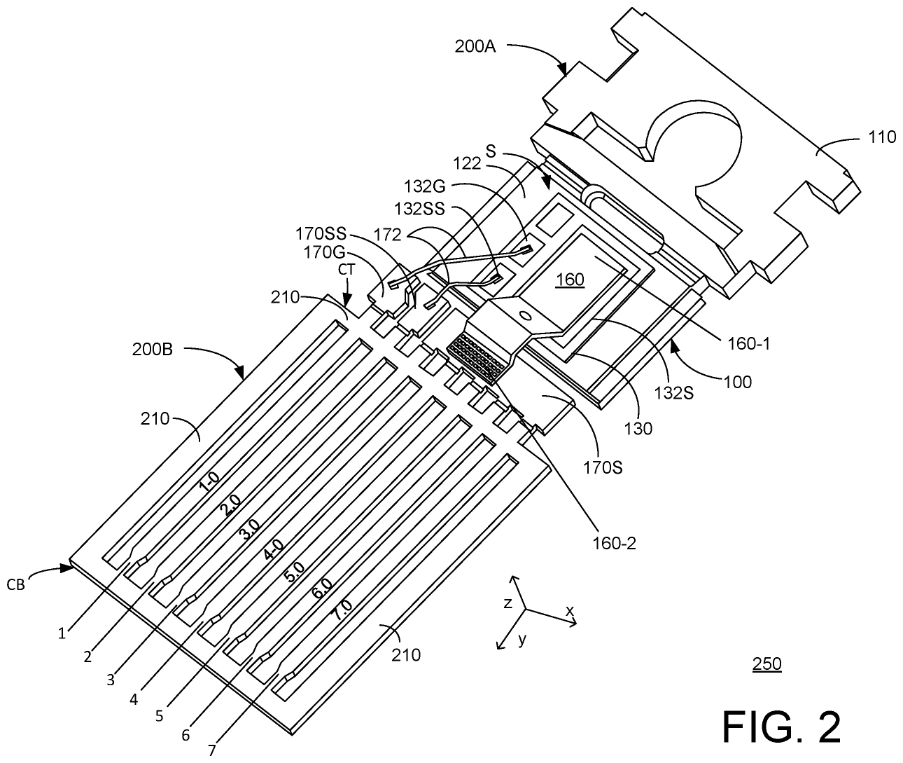

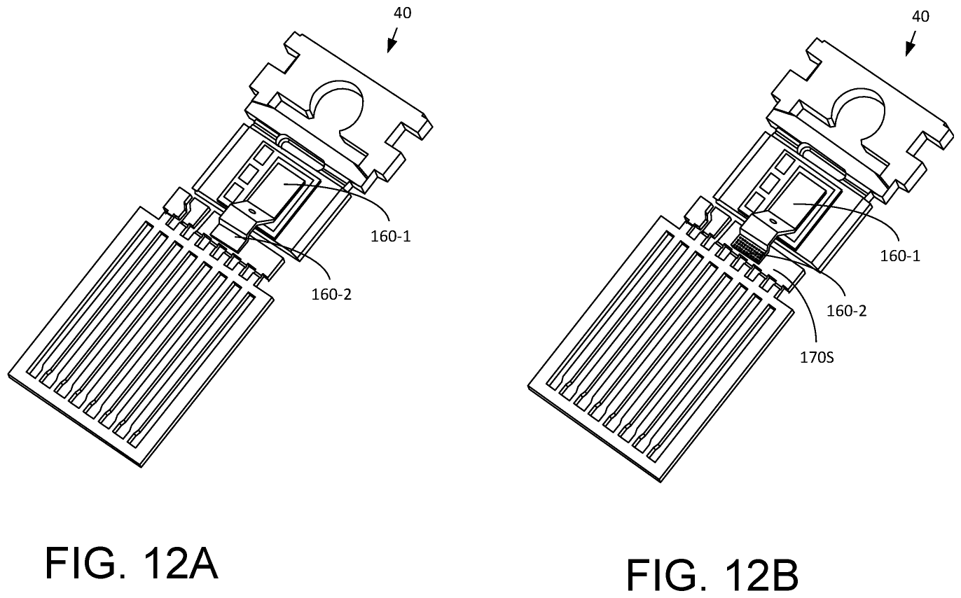

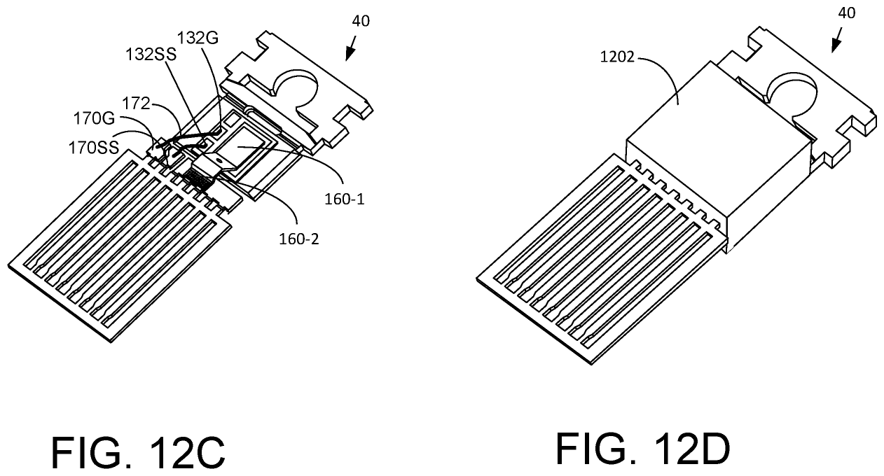

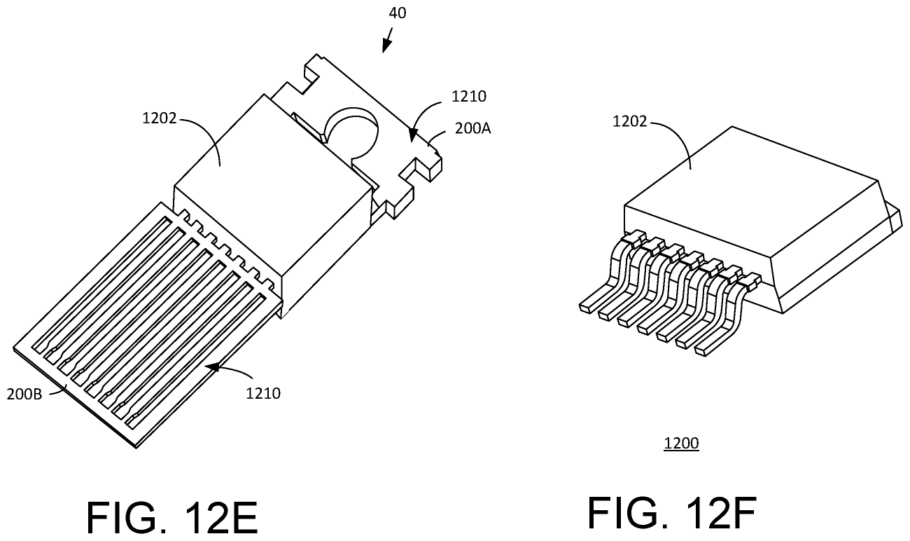

FIG. 2 shows, in a plan view, an assembly of components 250 at an intermediate stage of construction of a semiconductor die package (e.g., a discrete semiconductor die package 1200 shown in FIG. 12F). The semiconductor die package can include components that are coupled together by sintering (e.g., Ag sintering, etc.) and can utilize a metal clip that is welded to a lead post for connecting the semiconductor die to the lead post in a lead frame structure, in accordance with the principles of the present disclosure.

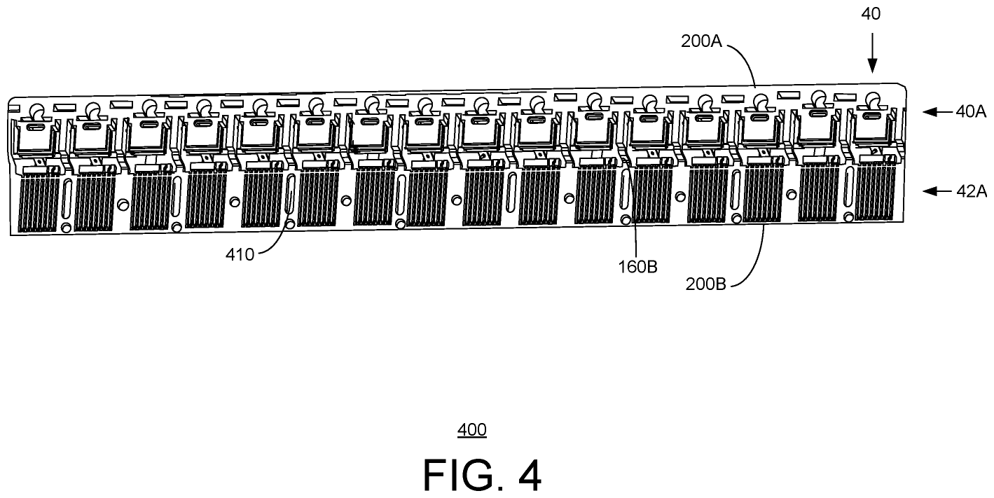

As shown in FIG. 2, the assembly of components 250 includes a lead frame structure 200A, and another lead frame structure 200B. Lead frame structure 200A and lead frame structure 200B may, for example, be made of copper or other metal. The lead frame structure 200A coupled to a corresponding lead frame structure 200B may be referred to herein as a lead frame unit (e.g., lead frame unit 40, FIG. 4).

Lead frame structure 200A may include a substrate 100 (e.g., copper block) attached to header 110. A die attach pad such as DAP 122 may be formed on a surface S of substrate 100.

Lead frame structure 200B may include a plurality of strips of metal or leads (e.g., lead 1, lead 2, lead 3, lead 4, lead 5, lead 6 and lead 7). An annular ring or collar 210 having, for example, a width CW (in a x direction) and a height CH (in a y direction) may hold portions (e.g., lead portion 1-0, lead portion 2-0, lead portion 3-0, lead portion 4-0, lead portion 5-0, lead portion 6-0 and lead portion 7-0, etc.) of the plurality of strips of metal (e.g., leads 1-7). These lead portions may extend (in the y direction) from a top CT of collar 210 to a bottom CB of collar 210, and may generally lie in the plane (e.g., x-y plane) of collar 210. These lead portions may be precursors of the external terminals (e.g., gate, source sense, and source terminals) of the package in which lead frame structure 200B is used.

The lead portions, including lead portion 1-0, lead portion 2-0, lead portion 3-0, lead portion 4-0, lead portion 5-0, lead portion 6-0 and lead portion 7-0, etc., may extend above the top CT of collar 210 to form lead posts such as a gate lead post 170G, a source sense lead post 170SS, and a source lead post 170S. Source lead post 170S may be common to lead portion 3-0, lead portion 4-0, lead portion 5-0, lead portion 6-0 and lead portion 7-0. In example implementations, gate lead post 170G, source sense lead post 170SS, and source lead post 170S may be coated or plated with nickel (Ni).

As shown in FIG. 2, in the assembly of the semiconductor die package, a semiconductor die 130 may be placed on DAP 122 on substrate 100 of lead frame structure 200A. Semiconductor die 130 may be attached to DAP 122 of lead frame structure 200A by an Ag sinter (not visible) disposed between the die and the DAP.

A surface of the semiconductor die may expose a source contact pad 132S, a gate contact pad 132G, and source sense contact pad 132SS. In example implementations, gate contact pad 132G and source sense contact pad 132SS may be electrically connected respectively to gate lead post 170G and source sense lead post 170SS (on lead frame structure 200B) by wire bonds 172. Wire bonds 172 may be aluminum or copper wire.

Further, in the example implementations, source contact pad 132S may be electrically connected to source lead post 170S by metal clip 160 (e.g., a copper clip). In example implementations, first end 160-1 of metal clip 160 may be attached to the source contact pad 132S on the semiconductor die by an Ag sinter (not visible).

In example implementation, second end 160-2 of metal clip 160 may be attached by a fusion bond 161 (FIG. 1) to source lead post 170S. Since source lead post 170S is common to lead portion 3-0, lead portion 4-0, lead portion 5-0, lead portion 6-0 and lead portion 7-0, any of leads 3-7 may be used as the external source terminal of the package. In some implementations, as discussed with references to FIG. 1, fusion bond 161 may be a joint (e.g., a welding joint) formed, for example, by joining (e.g., welding) second end 160-2 of metal clip 160 to lead post 3-0 of lead 3.

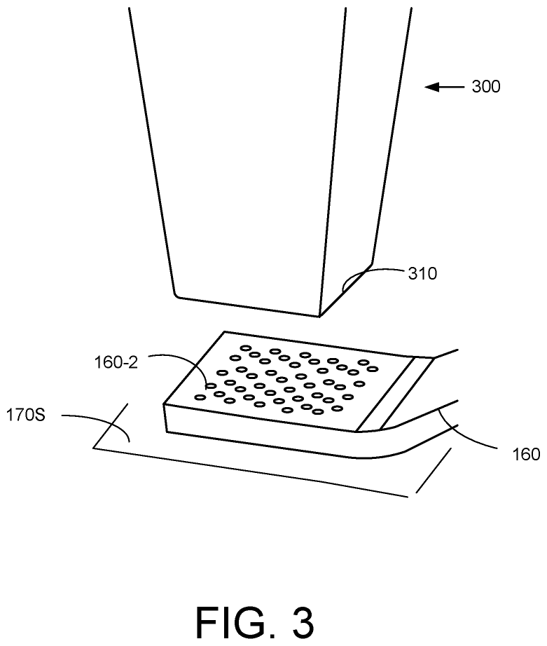

FIG. 3 schematically illustrates welding of second end 160-2 of metal clip 160 to source lead post 170S. A shown in FIG. 3, a welding tip 310 of a welding tool 300 can be used to apply pressure and temperature to second end 160-2 of metal clip 160 that is in contact with source lead post 170S to weld second end 160-2 to source lead post 170S.

In example implementations, for automated (or partially automated) assembly line construction of packages (e.g., device package), an array of lead frame structures including an array of lead frame structure 200A coupled to lead frame structure 200B may be supplied (e.g., to an assembly line tool) on a reeled substrate frame. The lead frame structure 200A coupled to lead frame structure 200B can be held in the reeled substrate frame between a pair of spaced-apart runner strips with indexing holes. The reeled substrate frame including the lead frame structures may be fabricated by plating copper traces and pads (on a printed circuit board (PCB) sheet). Each

[symbol]

FIG. 4 shows an example reeled substrate frame 400 including an array (e.g., array 40A) of lead frame structures 200A together with an array (e.g., array 42A) of lead frame structures 200B.

A lead frame structure 200A coupled to a corresponding lead frame structure 200B can be referred to herein as a lead frame unit 40. Each reeled substrate frame 400 may, for example, include multiple lead frame units 40. In example implementations, each reeled substrate frame 400 may, for example include ten to thirty lead frame units (e.g., sixteen lead frame units).

Reeled substrate frame 400 may include a spaced-apart holed runner strip. The runner strip may include indexing holes 410 to assist in positioning and aligning reeled substrate frame 400 in, for example, assembly line processing tools (e.g., a singulation tool, a die pick-and-place tool, material injection tools, etc.).

With renewed reference to FIG. 2, as previously mentioned, first end 160-1 of metal clip 160 may be attached to the source contact pad 132S on the semiconductor die 130 by an Ag sinter.

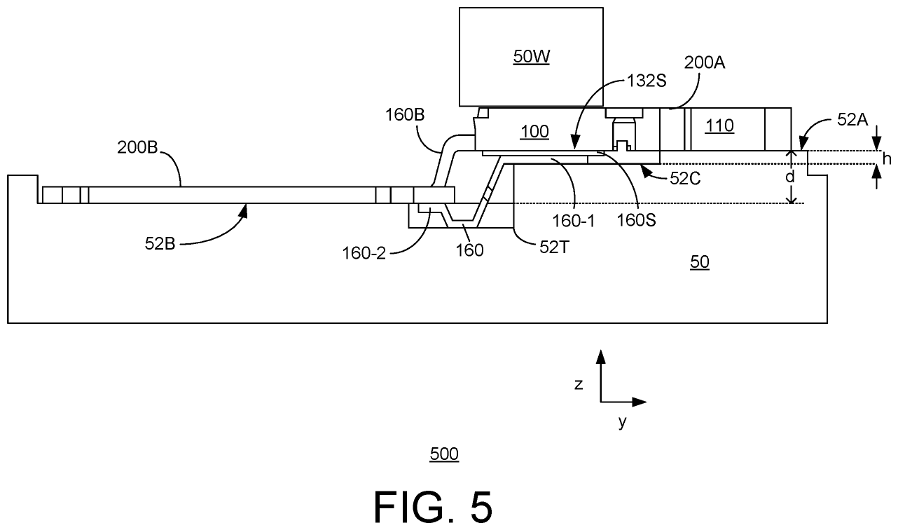

FIG. 5 schematically illustrates silver-based sintering of an end of metal clip 160 to the source contact pad 132S in a jig 500.

After the second end 160-2 of metal clip 160 is welded to source lead post 170S (FIG. 3), the lead frame structures may be flipped and placed in a support tray 50 in a jig 500. Support tray 50 may include a horizontal shelf 52A separated from another horizontal shelf 52B by a trough or trench 52T. Horizontal shelf 52A and horizontal shelf 52B may have a vertical height difference d corresponding, for example, to distance Z1 from the x-y plane of second end 160-2 to the x-y plane of first end 160-1 of metal clip 160 (shown in FIG. 1). Support tray 50 may further include a third horizontal shelf 52C adjacent to, but lower in height than horizontal shelf 52A (e.g., by a height h).

The lead frame structures may be flipped and placed in a support tray 50 as shown FIG. 5. Lead frame structure 200B may be connected lead frame structure 200B by a brace 160B in a reeled substrate frame (e.g., a reeled substrate frame 400, FIG. 4). In tray 50, lead frame structure 200B may be positioned horizontally on horizontal shelf 52B. Portions of metal clip 160 that are out of the x-y plane of lead frame structure 200B may be accommodated in trough or trench 52T. Further, lead frame structure 200A may be positioned horizontally on horizontal shelf 52A with a backside of substrate 100 in a horizontal position facing upward (in a z-direction). In this position, first end 160-1 of metal clip 160 may lie on third horizontal shelf 52C facing source contact pad 132S on substrate 100. A silver sinter material (e.g., sinter material 160S) may be disposed between source contact pad 132S and first end 160-1 of metal clip 160 on third horizontal shelf 52C.

Jig 500 may include a press or weight 50W that can be applied a backside of substrate 100 (as shown in FIG. 5) to apply pressure to the combination of source contact pad 132S, sinter material 160S and first end 160-1 of metal clip 160, to sinter metal clip 160 to source contact pad 132S.

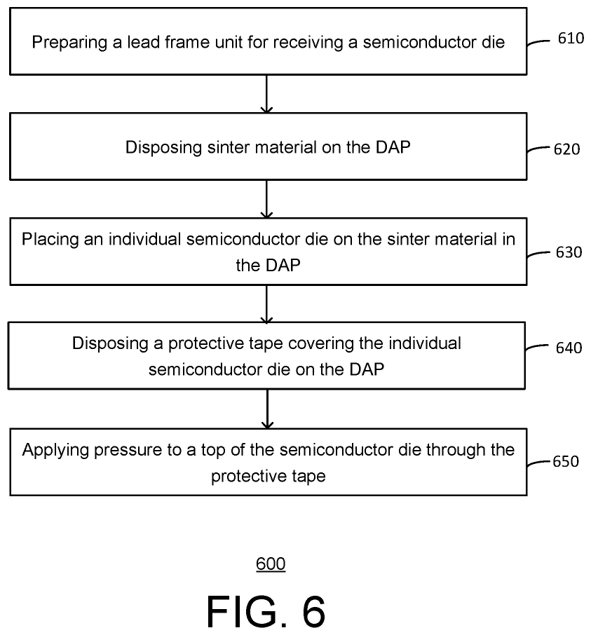

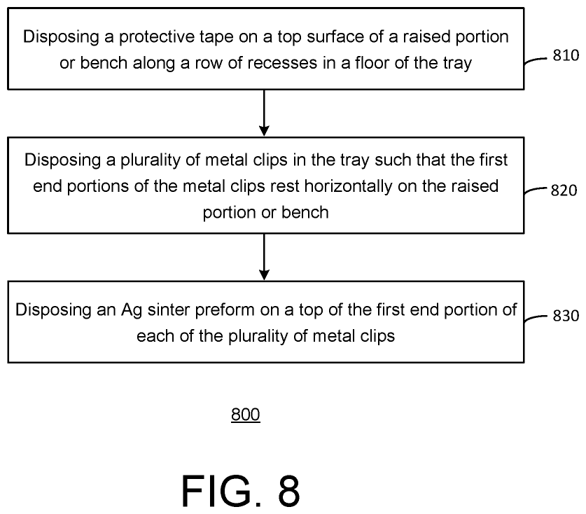

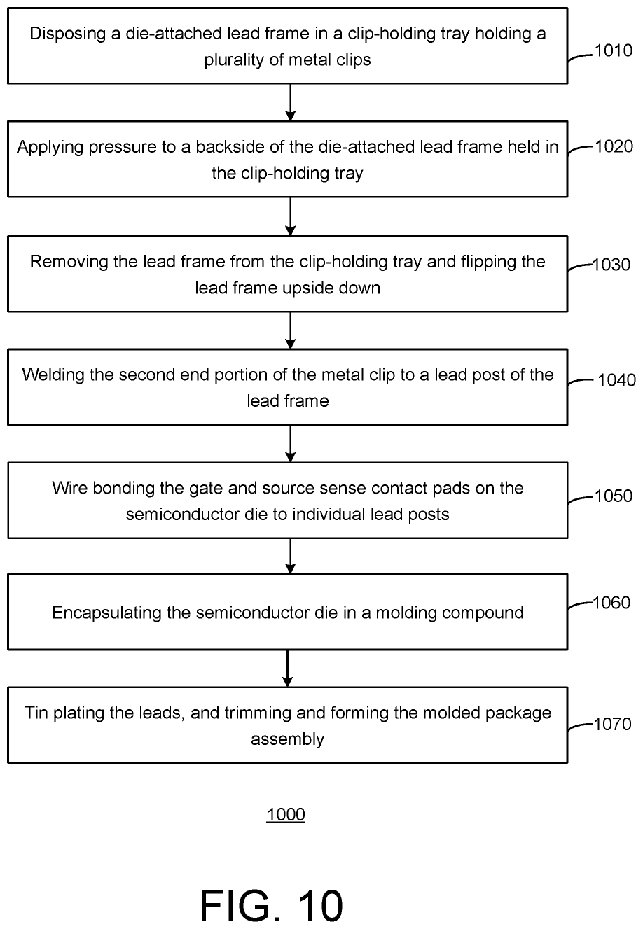

FIG. 6, FIG. 8, and FIG. 10 show methods that can be used to prepare various components or achieve various stages in the fabrication of a semiconductor die package.

FIG. 6 is a flow chart illustrating a method 600 for preparing a lead frame unit with a semiconductor die that is Ag sinter bonded to a DAP on a substrate.

Method 600 includes preparing a lead frame unit for receiving the semiconductor die (610). The lead frame unit may include a first lead frame structure including a DAP formed on a substrate, and a second lead frame structure containing a plurality of leads configured to serve as one of more external terminal of the package. Method 600 may be implemented in an automated (or partially automated) assembly line for construction of semiconductor die packages. The lead frame unit may be supplied as part of a reeled substrate frame (e.g., reeled substrate frame 400, FIG. 4). In the reeled substrate frame, the first lead frame structure and the second lead frame structure in the lead frame unit may be joined together by a brace or strip connector. In the completed single die package, the first lead frame structure and the second lead frame structure are connected by a metal clip (e.g., metal clip 160, FIG. 2).

Preparing the lead frame unit for receiving the semiconductor die may include silver plating the DAP formed on the substrate in the first lead frame structure.

Method 600 further includes disposing a sinter (e.g., Ag sinter) material on the DAP (620). The Ag sinter material (e.g., an Ag particle paste) may be disposed as an Ag sinter tape applied on the DAP.

Method 600 further includes placing an individual semiconductor die on the sinter material in the DAP (630). The placing of the individual semiconductor may be by a die pick-and-place operation by a tool in a fabrication assembly line.

Method 600 further includes disposing a protective tape on the DAP covering the individual semiconductor die (640), and applying pressure to a top of the semiconductor die through the protective tape (650). The pressure applied to the top of the semiconductor die may attach the semiconductor die to the DAP by high pressure sintering. The high pressure may be applied by a press tool in a fabrication assembly line. The protective tape may protect the semiconductor from damage caused by contact with the press tool.

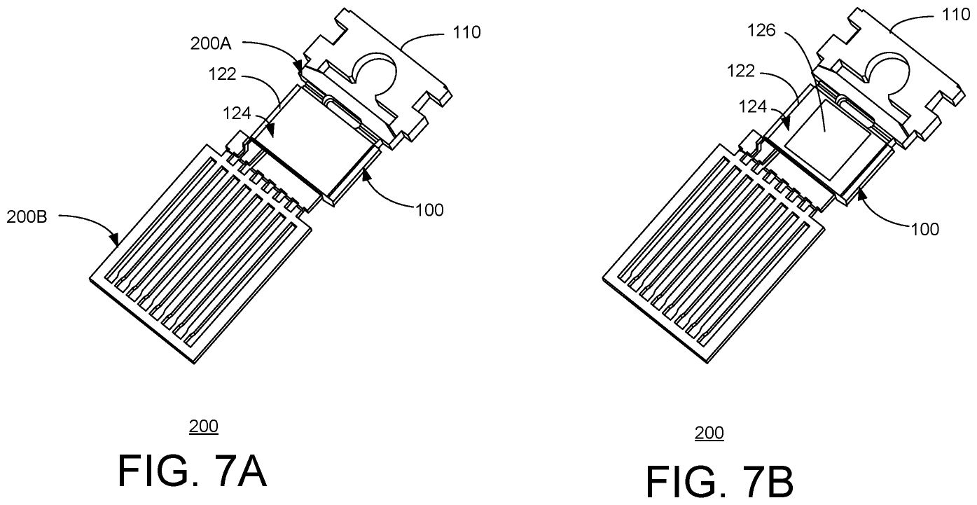

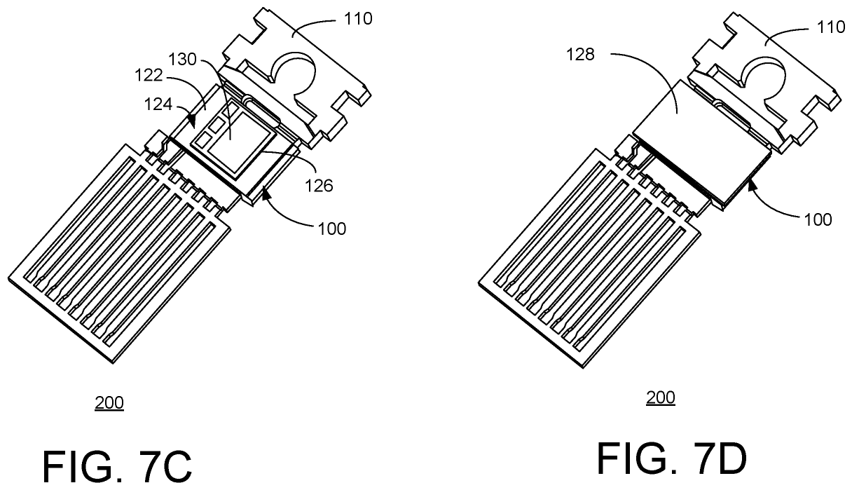

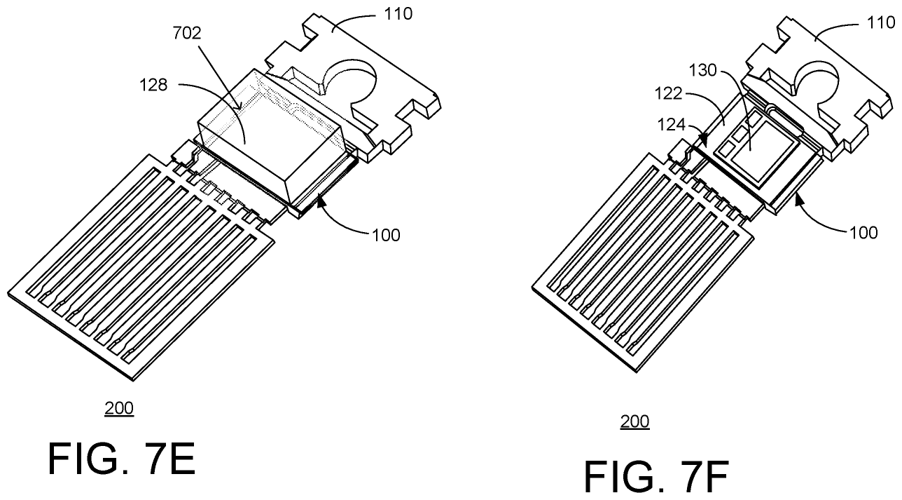

FIG. 7A through FIG. 7E show views of a lead frame unit at various stages of a process for Ag sinter bonding a semiconductor die to a DAP in a lead frame structure (e.g., lead frame 200).

FIG. 7A shows an example lead frame 200 (as also shown assembly of components 250 in FIG. 2). The lead frame unit includes a lead frame structure 200A and a lead frame structure 200B. Lead frame structure 200A include a substrate 100 on which a DAP (e.g., DAP 122) is formed. In example implementations, at a first stage of construction, DAP 122 is plated or coated with silver. In FIG. 7A, the silver plating is indicated as Ag plating 124.

In the next stage of construction, as shown in FIG. 7B, an Ag sinter tape 126 may be applied to DAP 122

In the next stage of construction, as shown in FIG. 7C, a semiconductor die (e.g., semiconductor die 130) may be placed on the Ag sinter tape 126 in DAP 122. Semiconductor die 130 may be placed in DAP in a pick-and-place operation in an assembly line.

In the next stage of construction, as shown in FIG. 7D, a protective tape may be disposed over substrate 100 to cover the semiconductor die (e.g., semiconductor die 130) placed on the Ag sinter tape 126 in DAP 122.

In the next stage of construction, as shown in FIG. 7E, a press or a weight (e.g., weight 702) may be disposed on protective tape 128 over substrate 100. The press or weight may apply pressure to semiconductor die 130 through the protective tape 128 and sinter bond the semiconductor die (e.g., semiconductor die 130) placed on the Ag sinter tape 126 to DAP 122. Protective tape 128 may protect semiconductor die 130 die from damage that may be caused by direct contact with weight 702. After the sinter bond is completed, the press or weight (e.g., weight 702) may be removed to result in a lead frame unit with a semiconductor die that is Ag sinter bonded to a DAP on a substrate. Lead frame 200 with semiconductor die 130 that is Ag sinter bonded to DAP 122 is shown, for example, in FIG. 7F.

FIG. 8 is a flow chart illustrating a method 800 for preparing metal clips (e.g., metal clip 160) with an Ag sinter preform for sinter bonding the metal clips to a lead frame 200.

Method 800 may include holding a plurality of metal clips (e.g., metal clip 160) a clip-holding tray. The plurality of metal clips (e.g., metal clip 160) in the clip holding tray may be processed concurrently in an assembly line. In example implementations, the plurality of metal clips (or portions of the metal clips) may be initially silver plated.

The holding tray may include a row of recesses in the floor of the tray and a raised portion or bench along the row of recesses. Method 800 may include disposing a protective tape on a top surface of a raised portion or bench along a row of recesses in a floor of the holding tray (810), and disposing the plurality of metal clips in the tray such that the first end portions (e.g., first end 160-1 of metal clip 160) rest horizontally on the raised portion or bench (820).

In this scenario, placing the metal clips in the tray may include placing the second end portions (e.g., second end 160-2 of metal clip 160) to rest in the recesses in the floor of the tray, while the first end portions (e.g., first end 160-1 of metal clip 160) rest horizontally on the raised portion or bench along the row of recesses.

Method 800 further includes disposing an Ag sinter preform on a top of the first end portion of each of the metal clips (830). A pick-and-place tool may be used to dispose an Ag sinter preform on a top of each of the first end portions (e.g., first end 160-1 of metal clip 160) resting horizontally on the raised portion or bench along the row of recesses.

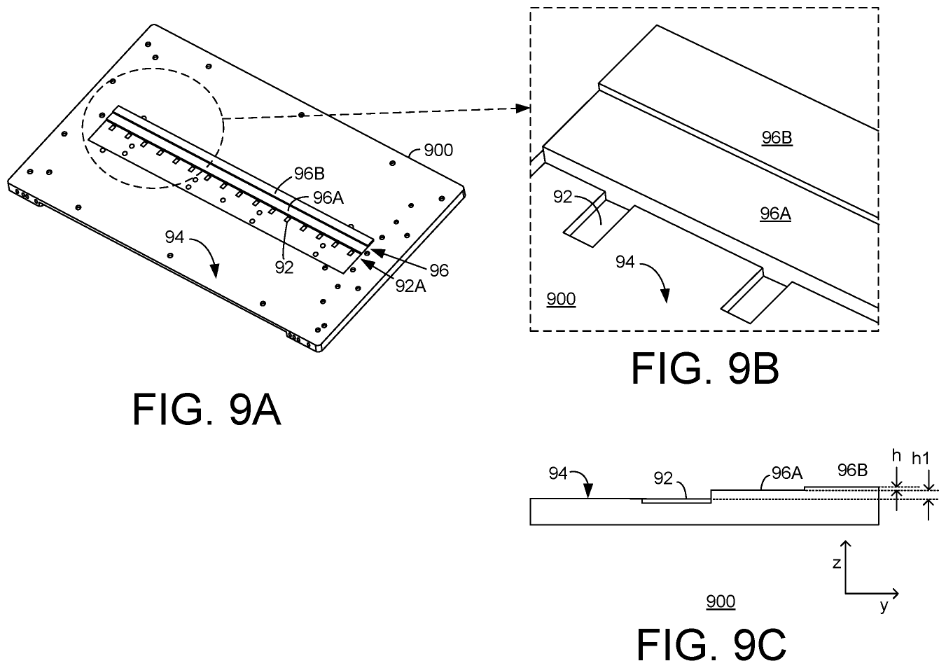

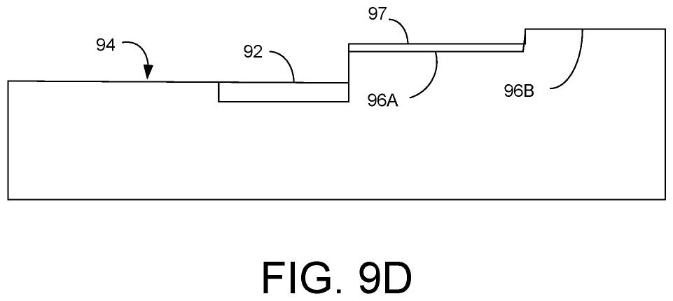

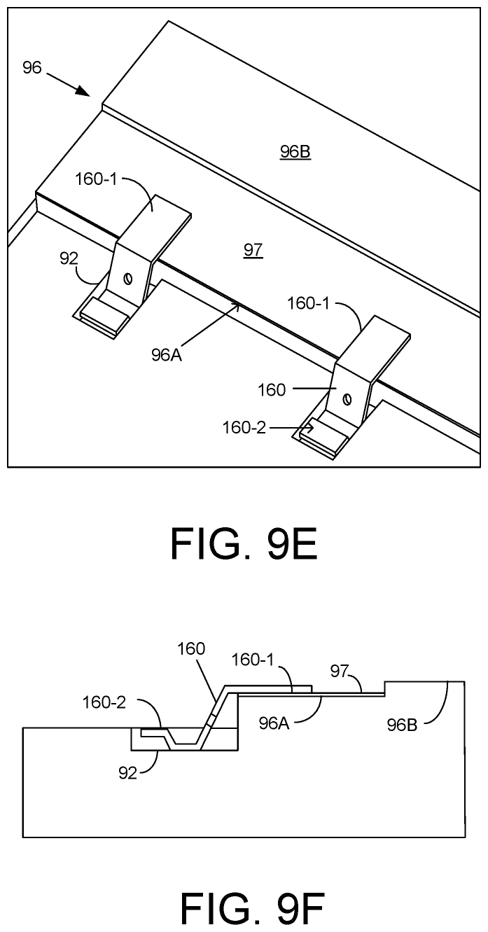

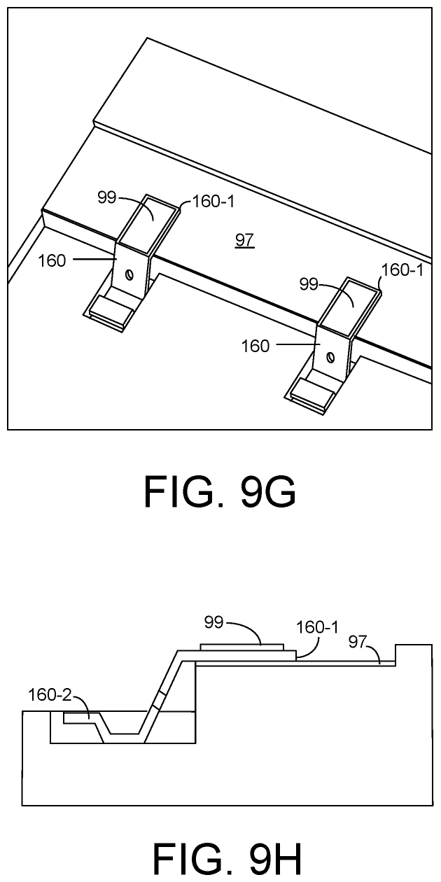

FIG. 9A through FIG. 9E show illustrate various stages of a process for disposing Ag sinter preforms on metal clips for sinter bonding.

FIG. 9A is an illustration of an example clip-holding tray 900 that can be used to hold a plurality of the metal clips for processing. FIG. 9B shows an exploded view of a portion of clip-holding tray 900, and FIG. 9C shows a cross-sectional view of clip-holding tray 900. Clip-holding tray 900 may include a raised seat or bench 96 alongside an array of recesses or trenches (e.g., array 92A of recess 92) cut in the floor (e.g., floor 94) of the tray. Raised seat or bench 96 may include two adjacent strips or shelves (e.g., seat 96A and seat 96B) that are at different heights (in the z direction) above floor 94. As shown in FIG. 9C, seat 96A can be at a height h1 above floor 94 and seat 96B can be at height h above seat 94A.

In advance of placing the plurality of metal clips (e.g., metal clip 160) in the clip-holding tray 900, a protective film 97 is disposed on at least a part of raised seat or bench 96 in clip-holding tray 900. FIG. 9D shows, for example, a protective film 97 disposed on seat 96A of the raised portion or bench 96 in clip-holding tray 900.

FIG. 9E and FIG. 9F show a plurality of metal clips 160 disposed in the tray such that the first end portions (e.g., first end 160-1 of metal clip 160) rest horizontally on protective film 97 disposed on seat 96A in the raised seat or bench 96. The second end portions (e.g., second end 160-2 of metal clip 160) rest in the recesses (e.g., recess 92) in the floor of the tray.

FIG. 9G and FIG. 9H show Ag sinter preform 99 disposed on the first end portions (e.g., first end 160-1 of metal clip 160) that rest horizontally on protective film 97 disposed on seat 96A of the raised seat or bench 96.

FIG. 10 is a flow chart illustrating a method 1000 combining the results of method 600 and method 800 to fabricate a discrete semiconductor die package.

Method 1000 includes disposing a die-attached lead frame in a clip-holding tray holding a plurality of metal clips (1010). The die-attached lead frame may include a plurality of lead frame units with each including a semiconductor die that is Ag sintered to a DAP. The semiconductor die may have a top surface that exposes a source contact pad, a gate contact pad, and a source sense contact pad. The plurality of metal clips in the clip-holding tray holding the plurality of metal clips may have Ag sinter preform disposed on a top of each of the first end portions of the metal clips that rest on a raised bench in the clip-holding tray. Disposing the die-attached lead frame in the clip-holding tray holding the plurality of metal clips 1010 may include disposing the die-attached lead frame such that the Ag sinter preform disposed on the top of each of the first end portions is aligned with and abuts the source contact pad of a corresponding semiconductor die (that is Ag sintered to the DAP).

Method 1000 further includes applying pressure to a backside of the die-attached lead frame held in the clip-holding tray (1020). A press or other pressure tool can be used to apply (sintering) pressure to a backside of the semiconductor die on which the source contact pad is formed. The applied pressure can sinter the first end portion of the metal clip with the Ag sinter preform (Ag sinter preform 99, FIG. 9G and FIG. 9H) to the source contact pad on the semiconductor die.

Method 1000 further includes removing the lead frame from the clip-holding tray and flipping the lead frame upside down (1030), and welding the second end portion of the metal clip to a lead post of the lead frame (1040).

Method 1000 further includes wire bonding the gate and source sense contact pads on the semiconductor die to individual lead posts (1050). Al wire or Cu wire may be used for wire bonding the gate and source sense pads.

Method 1000 further includes wire bonding the gate and source sense contact pads on the semiconductor die to individual lead posts (1050). Al wire or Cu wire may be used for wire bonding the gate and source sense pads.

Method 1000 may involve encapsulating the semiconductor die in a mold body after connecting the leads to the respective device contact pads. Method 1000 may further involve removing (e.g., cutting) the annular collar to individually separate the leads attached to the annular collar. Method 1000 may further include shaping the portions of the leads extending outside the mold body as external terminals of the discrete semiconductor device package.

Method 1000 further includes encapsulating the semiconductor die in a molding compound (1060), and trimming and forming the molded package assembly (1070).

Method 1000 may include plating (e.g., tin plating) the leads before trimming and forming the molded package assembly.

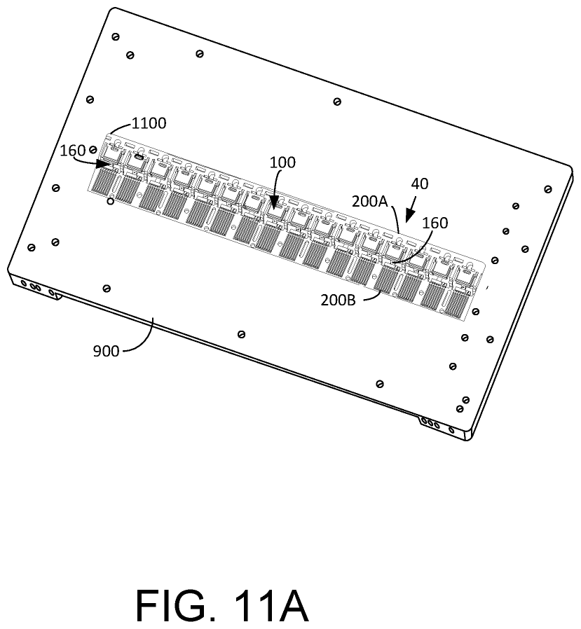

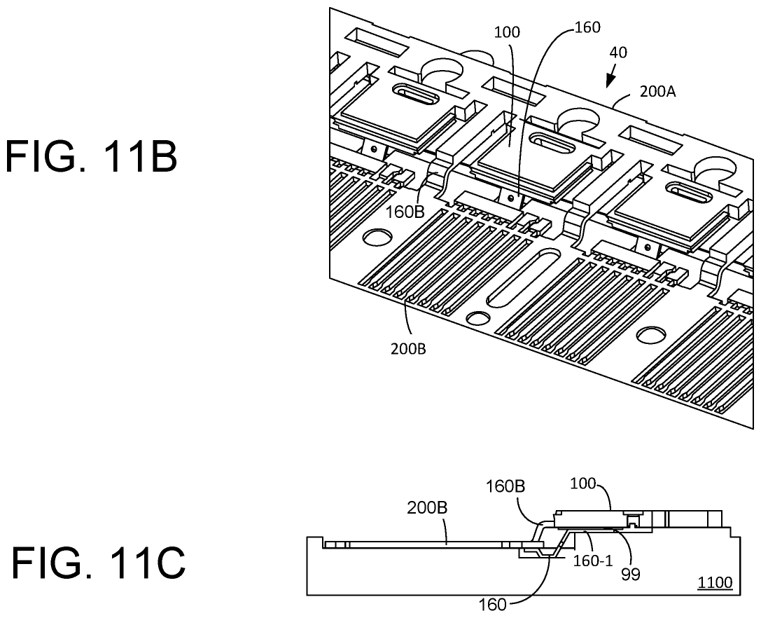

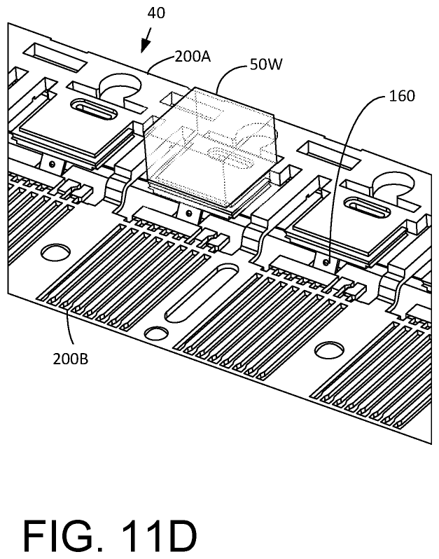

FIG. 11A through FIG. 11D and FIG. 12A through FIG. 12F show various views of a package assembly at various steps of method 1000.

FIG. 11A shows a plan view of a reeled substrate frame 1100 disposed in a clip-holding tray (e.g., clip-holding tray 900).

Reeled substrate frame 1100 may include a plurality of lead frame units 40. Each lead frame unit may include a semiconductor die attached to a DAP of a substrate (e.g., substrate 100), for example, using method 600 described above. The semiconductor die and the DAP, which are on a front side of the substrate, are not visible in the view shown in FIG. 11A. Clip-holding tray 900 may include a plurality of metal clips 160 that have an Ag sinter preform on a top of the first end 160-1 of each of the metal clips. The Ag sinter preforms, and the first end portions are not visible in the view shown in FIG. 11A. The metal clips may be prepared with the Ag sinter preform using, for example, method 800 described above.

Reeled substrate frame 1100 may be positioned in clip-holding tray 900 such that a source contact pad (e.g., source contact pad 132S) in the semiconductor die attached to the DAP is aligned with and contacts the Ag sinter preform on a corresponding metal clip 160.

FIG. 11B shows an exploded view of a portion of the reeled substrate frame disposed in the clip holding tray, and FIG. 11C shows a cross-sectional view of the reeled substrate frame disposed in the clip holding tray.

FIG. 11D shows the exploded view of the portion of the reeled substrate frame (as in FIG. 11B) with a press or weight 50W applied to a backside of substrate 100 to apply pressure to the combination of source contact pad 132S, Ag sinter preform 99 and first end 160-1 of metal clip 160. The applied pressure can sinter bond the metal clip 160 to source contact pad 132S at low temperatures.

FIG. 12A shows a plan view of a frame unit 40 after reeled substrate frame 1100 is removed from the clip-holding tray and flipped upside down. FIG. 12B shows a view of frame unit 40 after second end 160-2 of metal clip 160 is welded to a lead post (e.g., source lead post 170S) as discussed previously with reference to FIG. 3.

Further, FIG. 12C shows a plan view of frame unit 40 after wire bonds are formed between device contact pads (e.g., gate contact pad 132G, and source sense pad 132SS) are connected to lead post (e.g., gate lead post 170G and source sense lead post 170SS) by wire bonds 172. Wire bonds 172 may, for example, be aluminum wire bonds.

Further, FIG. 12D shows a plan view of frame unit 40 in which the semiconductor die is encapsulated in a mold body 1202 made of an epoxy molding compound (EMC), after the wire bonds 172 (FIG. 12C) are formed.

Further, FIG. 12E shows a plan view of frame unit 40 after portions of the lead frame structures 200A and 200B outside mold body 1202 are plated with tin. The tin plating is indicated in FIG. 12E by arrows labelled 1210.

FIG. 12F show a 3-dimensional perspective view of a discrete semiconductor die package 1200 formed after trimming and forming operations on the molded body of FIG. 12E.

The trimming and forming operations involve removing (e.g., cutting) the annular collar (e.g., by singulation) to individually separate the leads attached to the annular collar (e.g., collar 210, FIG. 2) and shaping the leads extending outside the mold body as external terminals of the discrete semiconductor device package.

The Ag sinter material used in the foregoing methods may, for example, be Ag particle paste. Further, the Ag sintering steps described in the foregoing may involve a low temperature sintering treatment in addition to application of pressure to the components. In example implementations, the low temperature sintering may involve sintering temperatures, for example, in a range of about 200° C. to about 300° C. (e.g., 250° C.). The sintering process can result in the sintering material (e.g., Ag species) diffusing completely into the sintered components.

In example implementations, the package (e.g., a discrete semiconductor die package 1200) may be of a type intended for surface mounting on a circuit board with the external terminals shaped to lie flat on a circuit board (e.g., PCB) surface. In the example shown in FIG. 12F, the lead portions are bent so that their end portions lie flat in the x-y plane along the bottom of mold body 1202.

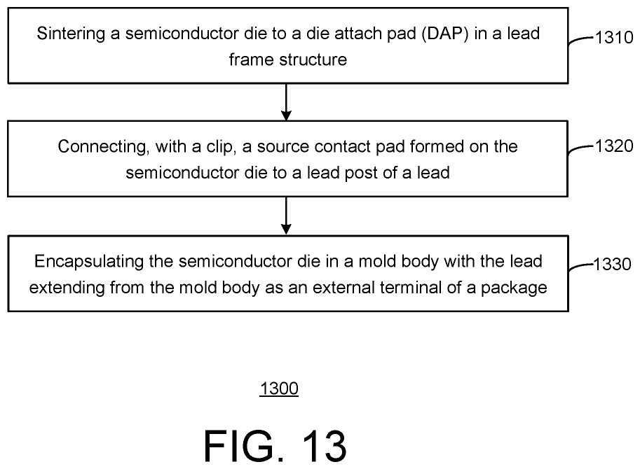

FIG. 13 is a flow chart illustrating an example method 1300 for packaging a semiconductor die. The semiconductor die may include a silicon carbide (SiC) power transistor.

Method 1300 includes sintering a semiconductor die to a die attach pad (DAP) in a lead frame structure (1310), connecting, with a clip, a source contact pad formed on the semiconductor die to a lead post of a lead (1320), and encapsulating the semiconductor die in a mold body with the lead extending from the mold body as an external terminal of a package (1330).

In method 1300, sintering the semiconductor die to the DAP includes disposing a silver particle paste between the semiconductor die and the DAP, and applying pressure on the semiconductor die.

In method 1300, connecting, with a clip, the source contact pad on the semiconductor die to a lead post of a lead with a clip includes sintering a first end of the clip to the source contact pad. Sintering the first end of the clip to the source contact pad includes disposing a silver sinter preform on a top of first end of the clip abutting the source contact pad, and applying pressure to a backside of semiconductor die on which the source contact pad is formed.

Further, in method 1300, connecting, with a clip, the source contact pad formed on the semiconductor die to the lead post of the lead includes welding a second end of the clip to the lead post of the lead.

It will be understood that, in the foregoing description, when an element, such as a layer, a region, a substrate, or component is referred to as being on, connected to, electrically connected to, coupled to, or electrically coupled to another element, it may be directly on, connected or coupled to the other element, or one or more intervening elements may be present. In contrast, when an element is referred to as being directly on, directly connected to or directly coupled to another element or layer, there are no intervening elements or layers present. Although the terms directly on, directly connected to, or directly coupled to may not be used throughout the detailed description, elements that are shown as being directly on, directly connected or directly coupled can be referred to as such. The claims of the application, if any, may be amended to recite exemplary relationships described in the specification or shown in the figures.

As used in the specification and claims, a singular form may, unless indicating a particular case in terms of the context, include a plural form. Spatially relative terms (e.g., over, above, upper, under, beneath, below, lower, and so forth) are intended to encompass different orientations of the device in use or operation in addition to the orientation depicted in the figures. In some implementations, the relative terms above and below can, respectively, include vertically above and vertically below. In some implementations, the term adjacent can include laterally adjacent to or horizontally adjacent to.

Some implementations may be implemented using various semiconductor processing and/or packaging techniques. Some implementations may be implemented using various types of semiconductor processing techniques associated with semiconductor substrates including, but not limited to, for example, Silicon (Si), Gallium Arsenide (GaAs), Gallium Nitride (GaN), Silicon Carbide (SiC) and/or so forth.

While certain features of the described implementations have been illustrated as described herein, many modifications, substitutions, changes, and equivalents will now occur to those skilled in the art. It is, therefore, to be understood that the appended claims are intended to cover all such modifications and changes as fall within the scope of the implementations. It should be understood that they have been presented by way of example only, not limitation, and various changes in form and details may be made. Any portion of the apparatus and/or methods described herein may be combined in any combination, except mutually exclusive combinations. The implementations described herein can include various combinations and/or sub-combinations of the functions, components and/or features of the different implementations described.

What is claimed is:

1. A package comprising:
a semiconductor die attached to a die attach pad by a first sinter bond;
a clip having a first end and a second end, the first end attached to a device contact pad on the semiconductor die by a second sinter bond, the second end attached to a post of a lead by a joint; and
a mold body encapsulating the semiconductor die.

2. The package of claim 1, wherein the first sinter bond and the second sinter bond are low temperature silver-based sinter bonds.

3. The package of claim 1, wherein lead with the second end of the clip attached to the post of the lead extends outside the mold body to form an external terminal of the package.

4. The package of claim 3, wherein the device contact pad is a source contact pad and wherein the external terminal is an external source terminal of the package.

5. The package of claim 1, wherein the device contact pad is a first device contact pad, and the lead is a first lead and wherein the semiconductor die further includes a second device contact pad that is connected by a wire bond to a post of a second lead.

6. The package of claim 5, wherein the wire bond is an aluminum wire bond.

7. The package of claim 5, wherein the second device contact pad is a gate contact pad and wherein the second lead extends outside the mold body to form an external gate terminal of the package.

8. The package of claim 1, wherein the semiconductor die includes a silicon carbide (SiC) power transistor.

9. A package comprising:
a semiconductor die attached to a die attach pad on a substrate, the semiconductor die having a source contact pad, a gate contact pad and a source sense pad;
a mold body encapsulating the semiconductor die; and
a clip connecting the source contact pad to a lead post of a lead forming an external terminal of the package, a first end of the clip being attached to the source contact pad by a sinter bond, a second end of the clip being attached to a lead post by a fusion bond, the lead post being an end of a lead extending outside the mold body to form an external source terminal of the package.

10. The package of claim 9, wherein the fusion bond is a silver sinter bond.

11. The package of claim 9, wherein the fusion bond is a welding joint.

12. The package of claim 9, wherein the gate contact pad and a source sense pad are connected by wires bonded to a respective gate lead post and a respective source sense lead post.

13. The package of claim 12, wherein the wires are aluminum wires.

14. The package of claim 9, wherein the semiconductor die includes a silicon carbide (SiC) power transistor.

15. A method comprising:
sintering a semiconductor die to a die attach pad (DAP) in a lead frame structure;
connecting a source contact pad formed on the semiconductor die to a lead post of a lead with a clip; and
encapsulating the semiconductor die in a mold body with the lead extending from the mold body as an external terminal of a package.

16. The method of claim 15, wherein sintering the semiconductor die to the DAP includes:
disposing a silver particle paste between the semiconductor die and the DAP; and
applying pressure on the semiconductor die.

17. The method of claim 15, wherein connecting the source contact pad on the semiconductor die to a lead post of a lead with a clip includes sintering a first end of the clip to the source contact pad.

18. The method of claim 17, wherein sintering the first end of the clip to the source contact pad includes:
disposing a silver sinter preform on a top of first end of the clip abutting the source contact pad; and
applying pressure to a backside of semiconductor die on which the source contact pad is formed.

19. The method of claim 15, wherein connecting a source contact pad formed on the semiconductor die to the lead post of the lead with the clip further comprises welding a second end of the clip to the lead post of the lead.

20. The method of claim 15, wherein the semiconductor die includes a silicon carbide (SiC) power transistor.
